(19) United States
(12) Patent Application Publication
(10) Pub. No.: US 2026/0005417 A1
(43) Pub. Date: Jan. 1, 2026

(54) DESIGN AND STRUCTURES OF HIGH-SPEED INTERCONNECTS FOR IMPROVED SIGNAL INTEGRITY

(71) Applicant: University of South Carolina, Columbia, SC (US)

(72) Inventors: Guoan Wang, Irmo, SC (US); Yingcong Zhang, Columbia, SC (US)

(73) Assignee: University of South Carolina, Columbia, SC (US)

(21) Appl. No.: 19/209,183

(22) Filed: May 15, 2025

Related U.S. Application Data
(60) Provisional application No. 63/647,742, filed on May 15, 2024.

(51) Int. Cl. H01P 3/08; H01P 5/18; H01P 11/00; H03H 7/01

(52) U.S. Cl. CPC H01P 3/081; H01P 5/185; H01P 11/003; H03H 7/1791

(57) ABSTRACT

An improved design methodology and new interconnect structures, which includes integrating interdigital trapezoidal tabs and defected microstrip line to effectively reduce far-end crosstalk including a new design method and unique structures aimed at enhancing signal integrity.

### TECHNICAL FIELD

The subject matter disclosed herein is generally directed to an improved design methodology and new interconnect structures, which includes integrating interdigital trapezoidal tabs and defected microstrip line to effectively reduce far-end crosstalk including a new design method and unique structures aimed at enhancing signal integrity.

### BACKGROUND

In recent years, significant advances in processing techniques have propelled the development of devices with heightened complexity, facilitating the integration of greater amounts of logics and transistors onto miniaturized integrated circuits and chips, which instigate a discernible trend towards increasing densities on printed circuit boards and silicon dies, aimed at pursuing systems featuring higher speed, wider bandwidth, and smaller size. Consequently, the electromagnetic performance of the interconnects plays a pivotal role in electronic systems as it directly impacts their signal integrity, due to suboptimal interconnects having the potential to introduce undesired electromagnetic interference (EMI), thereby compromising the quality of high-speed signal transmission.

Accordingly, it is an object of the present disclosure to reduce crosstalk issues by providing an improved surface tab routing method introducing interdigital trapezoidal tabs along the signal traces, which enables the closely placed traces to have a reduced far-end crosstalk (FEXT).

Citation or identification of any document in this application is not an admission that such a document is available as prior art to the present disclosure.

### SUMMARY

The above objectives are accomplished according to the present disclosure by providing in one instance an interconnect structure for reducing far-end crosstalk. The interconnect structure may include at least two traces formed substantially parallel to one another, a pattern etched onto at least one of the traces; and the interconnect structure may have a frequency from 1 to 18 GHz and a maximum FEXT reduction of up to 55 dB at 10.6 GHz. Further, the pattern etched into the at least one trace may comprise an LL shape etched at multiple locations on the at least one trace. Still further, the pattern etched into the at least one trace may comprise notches defined within a material forming the at least one trace. Even further, the pattern etched on the at least one trace may improve a self-inductance of the at least one trace as compared to a different trace with no pattern etched on the different trace. Moreover, a series of tabs may be formed onto at least one of the at least two traces. Still again, the series of tabs may improve a mutual capacitance value of the at least one trace as compared to a second different trace with no series of pattern etched on the second different trace. Even further, the series of tabs may be shaped as trapezoidal tabs. Further yet, self-inductance and mutual capacitance of the at least one of the two traces may be adjustable by configuring both the pattern etched and the series of tabs on the at least one of the traces. Yet still, FEXT may be reduced via concurrently increasing a mutual capacitance between adjacent traces and self-inductance of the at least two traces. Even further, the interconnect may decrease FEXT by at least 15 dB within an operation frequency range of 1 to 18 GHZ.

Further, the current disclosure provides methods for reducing far-end crosstalk. The method may include configuring an interconnect structure to comprise: at least two traces formed substantially parallel to one another; a pattern etched onto at least one of the traces; and configuring the interconnect structure to have a frequency from 1 to 18 GHz and a maximum FEXT reduction of up to 55 dB at 10.6 GHz. Further yet, the pattern etched into the at least one trace may be configured to form an LL shape etched at multiple locations on the at least one trace. Further yet, the pattern etched into the at least one trace may be configured to comprise notches defined within a material forming the at least one trace. Further again, the pattern etched on the at least one trace may be configured to improve a self-inductance of the at least one trace as compared to a different trace with no pattern etched on the different trace. Again still, the method may include configuring a series of tabs formed onto at least one of the at least two traces. Still further, the series of tab may be configured to improve a mutual capacitance value of the at least one trace as compared to a second different trace with no series of pattern etched on the second different trace. Yet further again, the series of tabs may be configured as trapezoidal tabs. Still furthermore, the method may include adjusting self-inductance and mutual capacitance of the at least one of the two traces via configuring both the pattern etched and the series of tabs on the at least one of the traces. Even further, the method may include reducing FEXT via concurrently increasing a mutual capacitance between adjacent traces and self-inductance of the at least two traces. Still further again, the interconnect structure may be configured to decrease FEXT by at least 15 dB within an operation frequency range of 1 to 18 GHz.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows an illustration of far-end crosstalk between a conventional signal traces model.

FIGS. 2A and 2B show at: (a) conventional transmission lines; (b) current tabbed routing structure; (c) new “LL” shape defected coupled lines, and (d) new “LL” shape defected tabbed routing.

FIGS. 3A, 3B, 3C, 3D, 3E, and 3F show graphs illustrating interconnect structures significantly improve the signal integrity in high-speed integrated circuits and communication systems

FIG. 4 shows Table 1, Specific FEXT values in dB for different cases at selected frequencies.

FIG. 5 shows at (a) a typical coupled line model and at (b) capacitive components in a coupled line model.

FIG. 6 shows at (a) a “LL” shaped defected coupled line unit and at (b) a “LL” shaped defected tabbed routing unit.

FIG. 7 shows an equivalent circuit of the “LL” shaped defected couple line.

FIGS. 8A and 8B show simulation results of various cases at: (a) FEXT and (b) insertion loss.

FIG. 9 shows Table 2, Comparison of Quasi-Static Capacitance, Inductance, and k_{f} Values for Different Structures.

FIG. 10 shows a design procedure flow of the “LL” shaped defected tabbed routing structures.

FIGS. 11A and 11B show: a schematic of (a) the proposed “LL” shaped defected coupled line and (b) “LL” shaped defected tabbed routing structure.

FIGS. 12A and 12B show optical images of the fabricated (a) coupled line, (b) “LL” shaped coupled line, (c) tabbed routing structure, and (d) “LL” shaped defected tabbed routing structure.

FIG. 13 shows Table 3, Comparison of Far-End Crosstalk Performance Among Various Structures.

FIGS. 14A and 14B show a comparison of various cases in term of (a) FEXT and (b) insertion loss.

FIGS. 15A, 15B, 15C, 15D, and 15E show at (a) a schematic of the circuit for eye diagram simulation in ADS software; (b) coupled line; (c) tabbed routing structure; (d) “LL” shaped defected coupled lines; and (e) “LL” shaped defected tabbed routing.

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping but rather should be read as “and/or” unless expressly stated otherwise. Similarly, a group of items linked with the conjunction “or” should not be read as requiring mutual exclusivity among that group but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the singular forms “a”, “an”, and “the” include both singular and plural referents unless the context clearly dictates otherwise.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g. given data set, art accepted standard, and/or with e.g. a given confidence interval (e.g. 90%, 95%, or more confidence interval from the mean), such as variations of +/−10% or less, +/−5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

The term “optional” or “optionally” means that the subsequent described event, circumstance or substituent may or may not occur, and that the description includes instances where the event or circumstance occurs and instances where it does not.

As used interchangeably herein, the terms “sufficient” and “effective,” can refer to an amount (e.g. mass, volume, dosage, concentration, and/or time period) needed to achieve one or more desired and/or stated result(s). For example, a therapeutically effective amount refers to an amount needed to achieve one or more therapeutic effects.

As used herein, “tangible medium of expression” refers to a medium that is physically tangible or accessible and is not a mere abstract thought or an unrecorded spoken word. “Tangible medium of expression” includes, but is not limited to, words on a cellulosic or plastic material, or data stored in a suitable computer readable memory form. The data can be stored on a unit device, such as a flash memory or CD-ROM or on a server that can be accessed by a user via, e.g. a web interface.

As used herein, the terms “weight percent,” “wt %,” and “wt. %,” which can be used interchangeably, indicate the percent by weight of a given component based on the total weight of a composition of which it is a component, unless otherwise specified. That is, unless otherwise specified, all wt % values are based on the total weight of the composition. It should be understood that the sum of wt % values for all components in a disclosed composition or formulation are equal to 100. Alternatively, if the wt % value is based on the total weight of a subset of components in a composition, it should be understood that the sum of wt % values the specified components in the disclosed composition or formulation are equal to 100.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present invention. Thus, appearances of the phrases “in one embodiment,” “in an embodiment,” or “an example embodiment” in various places throughout this specification are not necessarily all referring to the same embodiment but may. Furthermore, the particular features, structures or characteristics may be combined in any suitable manner, as would be apparent to a person skilled in the art from this disclosure, in one or more embodiments. Furthermore, while some embodiments described herein include some, but not other features included in other embodiments, combinations of features of different embodiments are meant to be within the scope of the invention. For example, in the appended claims, any of the claimed embodiments can be used in any combination.

All publications, published patent documents, and patent applications cited herein are hereby incorporated by reference to the same extent as though each individual publication, published patent document, or patent application was specifically and individually indicated as being incorporated by reference.

All patents, patent applications, published applications, and publications, databases, websites and other published materials cited herein are hereby incorporated by reference to the same extent as though each individual publication, published patent document, or patent application was specifically and individually indicated as being incorporated by reference.

### Kits

Any of the high-speed interconnects described herein can be presented as a combination kit. As used herein, the terms “combination kit” or “kit of parts” refers to the components, parts, pieces, modules, and any additional components that are used to package, sell, market, deliver, and/or provide the combination of elements or a single element, such as the high speed interconnects described herein. Such additional components include, but are not limited to, packaging, blister packages, and the like. When one or more of the components, parts, pieces, modules, and any additional components described herein or a combination thereof (e.g., a high speed interconnect provided alone or a bolt provided with constituent parts/pieces for installation) contained in the kit are provided simultaneously, the combination kit can contain the high speed interconnect alone or the high speed interconnect provided with other accoutrements for installation, modification, and/or upkeep. When the components, parts, pieces, modules, and any additional components described herein or a combination thereof and/or kit components are not provided simultaneously, the combination kit can contain the high-speed interconnect and constituent parts in separate combinations. The separate kit components can be contained in a single package or in separate packages within the kit.

In some embodiments, the combination kit also includes instructions printed on or otherwise contained in a tangible medium of expression. The instructions can provide information regarding the high-speed interconnects, installation/upkeep/maintenance information, information regarding use, etc. In some embodiments, the instructions can provide directions and protocols for installing a high-speed interconnect or providing maintenance to same. In some embodiments, the instructions can provide one or more embodiments of the methods for making high speed interconnects of the current disclosure as any of the methods described in greater detail elsewhere herein.

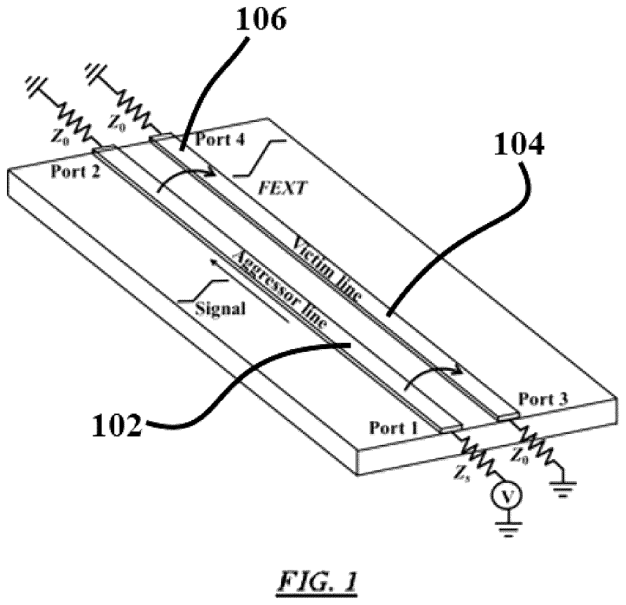

As signals are proximately positioned, which is depicted in FIG. 1, crosstalk noise arises due to electric and magnetic coupling between traces. Actually, electromagnetic crosstalk poses a significant challenge in electronic systems, especially with the increasing demand for miniaturization and high-speed transfer. Typically, the capacitive coupling between adjacent interconnects tends to be smaller compared to the inductive coupling, leading to the occurrence of far-end crosstalk (FEXT). Assuming one signal trace as the aggressor line 102 and the adjacent one as the victim line 104, the FEXT at port 4 106 can be defined as

$$F E X T = \frac{{V}_{in} l}{R T} \times \frac{1}{2 v} \times ( \frac{{C}_{m}}{{C}_{s}} - \frac{{L}_{m}}{{L}_{s}} ) \qquad ( 1 )$$

Where Vᵢₙ is the input voltage, l is the physical length of the signal trace, RT is signal rise time, v is signal velocity, Cₘ is mutual capacitance between two traces per length, Cₛ is self-capacitance per length, Lₘ is mutual inductance per length between two traces, Lₛ is self-inductance per length. According to the mathematical formula, the FEXT can be eliminated when the ratio of

$$\frac{{C}_{m}}{{C}_{s}}$$

approaches to the ratio of

$$\frac{{L}_{m}}{{L}_{s}} .$$

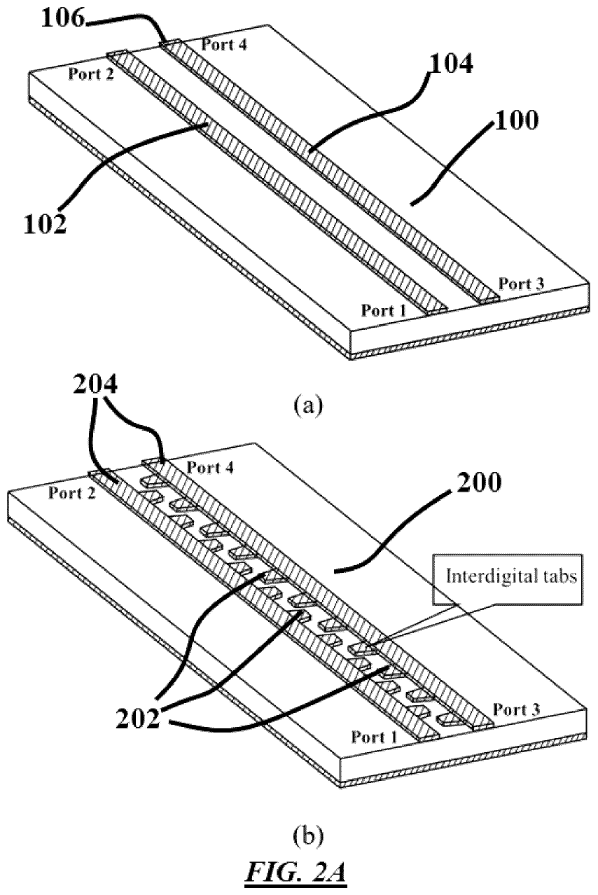

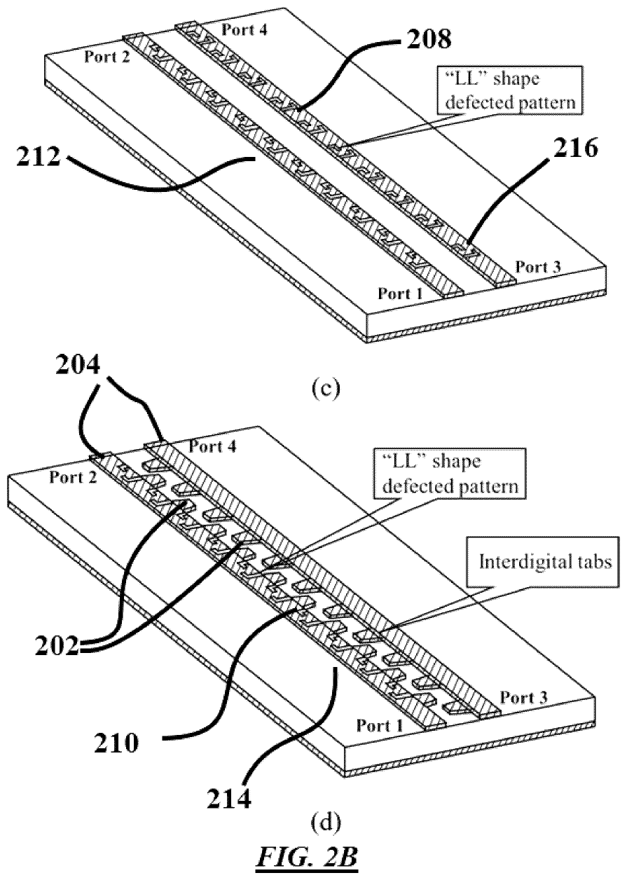

To effectively mitigate FEXT in practical applications, various methods have been applied in the industry world, including shielding, optimizing the geometry of interconnects, employing advanced materials, etc. For a practical instance, Intel Corporation has proposed a surface tab routing method for reducing crosstalk to enhance double data rate (DDR) channel performance, which is depicted in FIG. 2A at (b). Theoretically, crosstalk issues can be eliminated by providing adequate spacing between traces. However, in the high-density PCB package, signal channels often need to be proximately placed, leading to degradation in FEXT performance.

To tackle the inherent cross talk challenges and concurrently realize the reduced FEXT and the high-speed data transfer within a confined space, the current disclosure provides a surface tab routing method coupled with interdigital trapezoidal tabs 202 along the signal traces 204, which enables the closely placed traces to have a reduced FEXT.

This disclosure provides a novel design technique and new interconnect structures with the integration of interdigital trapezoidal tabs 202 structure and defected microstrip lines structure 206, which can effectively improve the interconnect signal integrity. Based on this innovative concept, two effective structures are introduced in this invention to eliminate the difference between capacitive coupling and inductive coupling of neighboring interconnects, thereby reducing FEXT. The two structures introduced in this invention include:
1. “LL” shape defected transmission lines 208 (FIG. 2B at (c)).
2. Tabbed routing structure with “LL” shape defected pattern 210 (FIG. 2B at (d)).

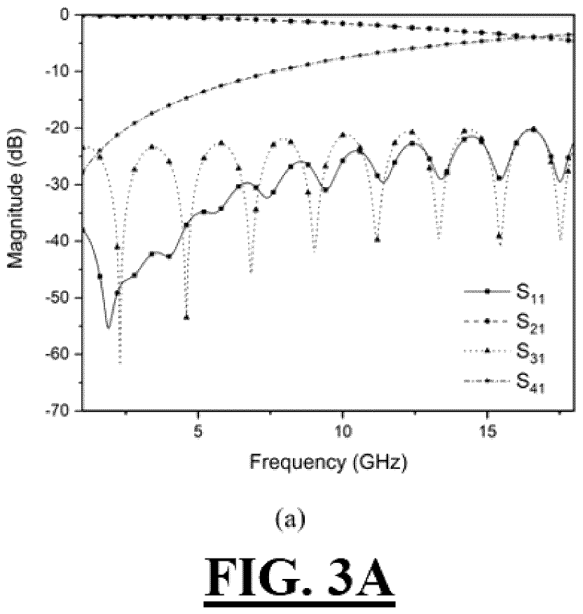

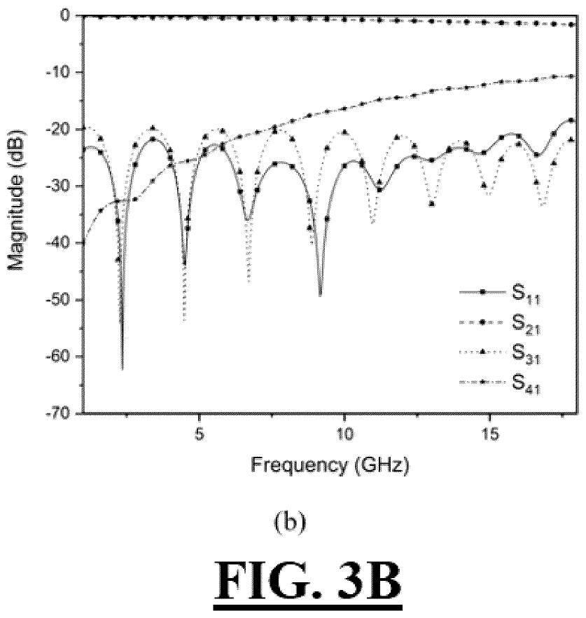

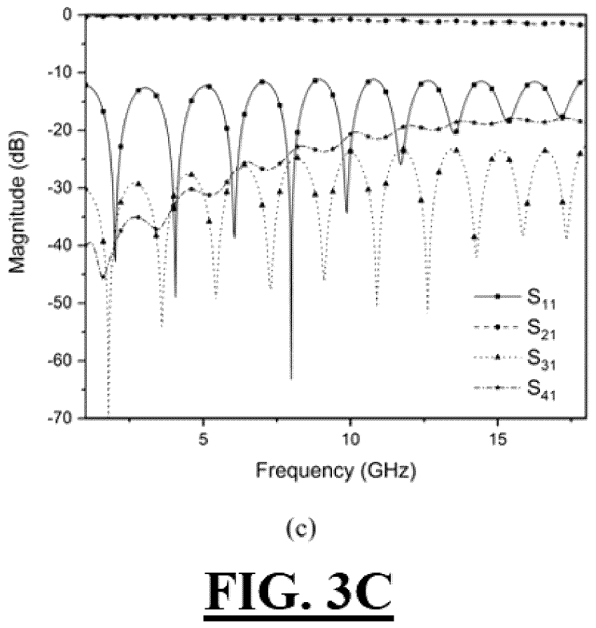

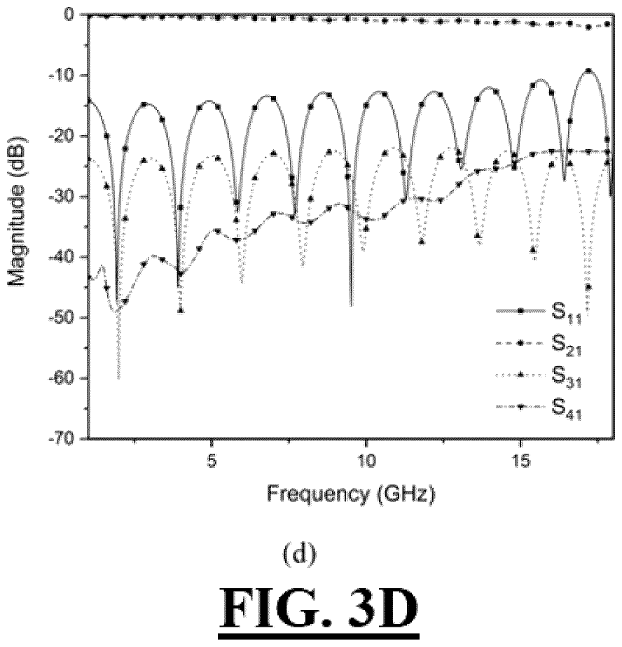

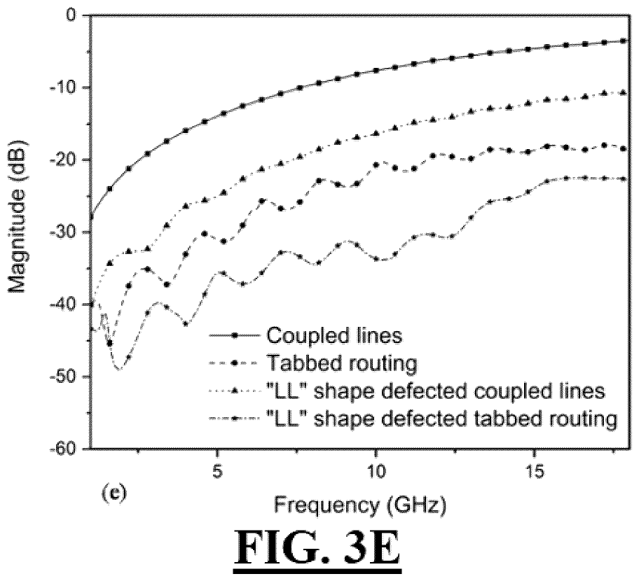

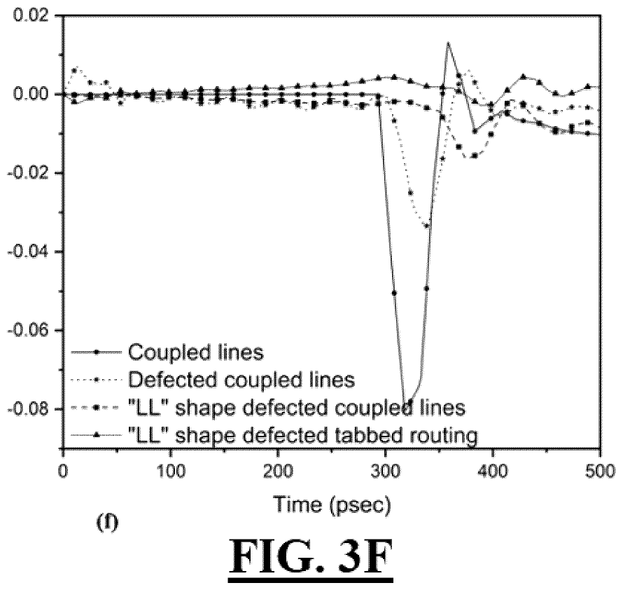

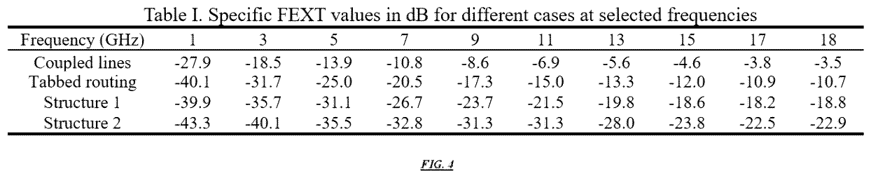

In the herein disclosed structure, the capacitive coupling (structure 1 and 2) is improved, while the inductive coupling (structure 1) is decreased to counterpoise the ratio difference, thereby mitigating the FEXT. As depicted in FIGS. 3A-3F, the proposed interconnect structures significantly improve the signal integrity in high-speed integrated circuits and communication systems.

FIGS. 2A and 2B at (a)-(d) illustrate the structures of conventional transmission lines 100, tabbed routing transmission lines 200, the herein disclosed “LL” shape defected transmission lines 212, and “LL” shape defected tabbed routing transmission lines 214, respectively. The conventional tabbed routing structure (FIG. 2A at (b)) features trapezoidal tabs 202 added along each trace 204, which aims to increase the mutual capacitance value. In the herein disclosed structure 1 the “LL” shape 216 defected transmission lines, shown in FIG. 2B at (c), “LL” patterns are etched on each trace, which can increase the self-inductance of the trace due to the various the physical geometrical dimensions of the “LL” pattern. “LL” refers to the shape of the etchings resembling letter ‘L’s facing one another, wherein one ‘L’ is inverted and facing the corresponding ‘L’ and the two ‘L’s may be of the same size or different sizes. These defective notches on transmission lines increase the self-inductance of the traces. They enable more space between the current flow of two adjacent transmission lines compared to the original transmission lines. FIG. 2B at (d) illustrates another advanced method and configuration as disclosed herein. The “LL” patterns are etched on the trace of the tabbed routing transmission lines. Similarly, the “LL” shape notches on traces improves the self-inductance of the trace. However, the integrated tabs along the traces improve the mutual capacitance value. With this method, the difference between the capacitive coupling and the inductive coupling can be better balanced to realize the FEXT reduction. Similarly, the “LL” shape notches on traces improves the self-inductance of the trace. Concurrently, the integration of tabs along the traces improves the mutual capacitance value. This method enables a more balanced adjustment between capacitive coupling and inductive coupling, thereby facilitating the reduction of FEXT.

All structures illustrated in FIGS. 2A and 2B are designed and simulated with the implementation on the same substrate (Standard Rogers RO4350 with εr=3.66, tan δ=0.004) and the same line length, width, and spacing dimensions (Length L=40 mm, width W=1.1 mm, and spacing s=1 mm). The original line has the characteristic impedance of 50Ω. Full-wave electromagnetic simulation software ANSYS HFSS is employed to perform the simulation work. FEXT on the victim line is represented by the scattering parameter S₄₁ (dot dash line with star symbol in FIGS. 3A-3D). The simulated S-parameters of FIGS. 2A and 2B at (a)-(d) are presented in FIGS. 3A-3D (a)-(d), respectively. FIG. 3E at (e) provides a direct comparison of the FEXT. It is observed that the herein disclosed structure can reduce the FEXT to a certain extent, while the herein disclosed structure 2 can reduce the FEXT to a greater extent. In summary, both herein disclosed structures exhibit reduced FEXT compared to current tabbed routing transmission lines techniques. To clearly demonstrate the difference in FEXT between each structure, specific FEXT values at selected frequencies are listed in Table I. This table makes the advantages of the herein disclosed structure readily visible.

The performance of all structures in the time domain is simulated using Advanced Design System (ADS) software. Each structure employs the same step wave as the excitation at the transmission line Port 1 and propagates to Port 2. This step wave rises from 0 V to 1 V with a rising time of 40 psec. The FEXT performance is detected at Port 4, and the results for all 4 structures are shown in FIG. 3F. It is observed that the original transmission line structure exhibits the highest wave peak, which is −0.08 V. The peak waveform values for the tabbed routing and the “LL” shape defected coupled lines are −0.033 V and 0.016 V, respectively. The “LL” shape defected tabbed routing records the lowest peak waveform value of 0.004 V.

This disclosure investigates a novel approach to mitigate far-end crosstalk (FEXT) in high density interconnects featuring distinctive “LL” shaped defected tabbed routing structures. The integration of “LL” shaped defected patterns and trapezoidal tabs are specifically engineered to concurrently increase capacitive coupling and decrease inductive coupling, mitigating FEXT to a greater extent. The proposed methodology is comprehensively analyzed utilizing the generated equivalent circuit model. Moreover, the capacitance and inductance matrices of coupled line, tabbed routing, and the proposed structures are extracted from full wave simulations and analyzed with numerical equations to ensure an accurate evaluation of FEXT. To validate the efficacy of the proposed designs, the structure prototypes are implemented with FR-4 printed circuit board. The S-parameters performance and eye diagrams are measured and compared. The measurement results demonstrate that the proposed structure effectively enhances FEXT behavior while ensuring robust high-speed signal propagation along the transmission paths. Specifically, FEXT is reduced by 15 dB within the frequency range of 1-18 GHZ, and the maximum reduction of 55 dB at 10.6 GHz. The proposed structure exhibits superior FEXT behavior improvement within a wide frequency range, indicating significant potential for practical wideband high-speed applications.

The rapid evolution of fifth-generation and beyond communication systems demands components and systems with more compact size, higher data transmission rate, and wider bandwidth, which necessitate the development of high-density integrated circuits and modules within the limited board area. Nevertheless, the increasing density of components and connecting traces poses significant challenges in mitigating the inevitable electromagnetic interference, commonly referred to as crosstalk (Xtlk). Crosstalk noise arises due to the proximity of signals at both near and far ends of the communication channel, which are termed near-end crosstalk and far-end crosstalk (FEXT), respectively. FEXT, in particular, continues to escalate along the signal trace, leading to signal degradation manifested in phenomena such as ground bounce, delay, and jitter [1].

Consequently, effectively reducing FEXT is crucial in modern and future communication systems. To ameliorate the impact of FEXT on signal transmission, the widely adopted approach involves implementing the 3-W rule [2], which requires maintaining a space between traces that is three times the width of the traces. However, adhering to this rule always requires a significant sacrifice of valuable space on printed circuit board (PCB) and silicon dies. Moreover, this strategy also suffers limited improvement in further mitigating FEXT. To address these challenges, a conductor guard trace methodology has been proposed, which suppresses FEXT with employed techniques such as via-stitching guard trace [3], serpentine guard trace [4], discontinuous structured guard lines [5], etc. Despite their effectiveness in further reducing FEXT, these methods require additional conductor spacing, which still equals to three times the trace width, and result in increased design complexity.

In an effort to minimize interconnect dimensions, other approaches, including decoupling capacitor [6], substrate rectangular groove [1], and thickened solder mask coating [7] have been explored. While these methods prove effective in reducing FEXT and minimizing signal spacing, their implementation involves a complex fabrication process. To overcome these issues, new strategies including short trapezoidal shaped tab routing structure [8], [9] and defected microstrip line structures [10], [11] have been proposed. These approaches achieve FEXT reduction by modifying physical geometrical dimensions of signal traces for optimized capacitive and inductive coupling, which provides case of fabrication, compact size, and FEXT reduction. However, FEXT performance and bandwidth remain constrained due to the inherent limitations of the structure geometry, including inductive tuning only, practical fabrication accuracy, and available board area. To further mitigate FEXT in tabbed routing structure, thin film techniques have also been introduced [12]. Despite providing an improved FEXT performance, this method suffers from standard PCB process compatibility and extra losses from the integrated new films, which are challenging for practical industry applications. Therefore, methods for further reducing FEXT with an easy and compatible fabrication process are highly desired in modern integrated systems with high density, wide bandwidth, and high-speed data transfer rates.

In this disclosure, an “LL” shaped defected tabbed routing structure is proposed to solve the abovementioned technical challenges. Through this proposed methodology, the FEXT can be reduced to a greater extent by concurrently increasing the mutual capacitance between the neighbor traces and the self-inductance of individual traces. With “LL” shaped defected patterns, the structure offers greater design flexibility, allowing for closer traces and more compact systems. Furthermore, the proposed structure encompasses easy implementation and an ultrawide bandwidth up to Ku band portion of the electromagnetic spectrum in the microwave range of frequencies from 12 to 18 gigahertz (GHz).

The rest of this disclosure is organized as follows. Section II delves into the analysis of FEXT in a conventional coupled lines structure and the proposed structures with theoretical formulas, analyzes the proposed “LL” shaped defected tabbed routing structure using the generated equivalent circuit model and the formulaic model. In Section III, the coupled line, tabbed routing, and the proposed structure are implemented, and the measurement results of the S-parameters and eye diagrams are analyzed to validate the efficacy of the proposed structure. Finally, Section IV concludes this disclosure.

### II. FEXT Analysis and Methodologies for FEXT Suppression

### A. Far-End Crosstalk in Conventional Coupled Lines

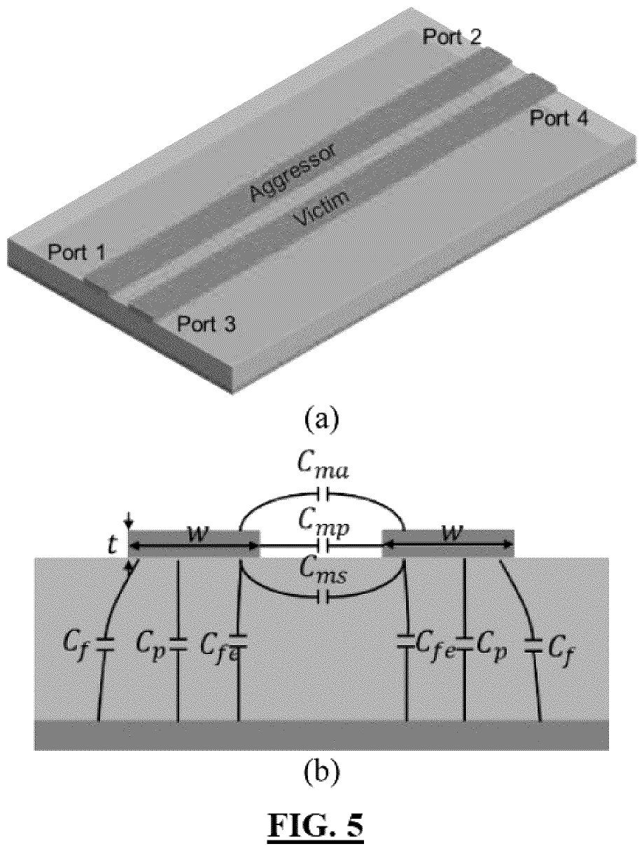

Crosstalk is an undesired phenomenon within electronic systems, arising from the interaction of electromagnetic fields produced by one trace with an adjacent one. In the pursuit of mitigating FEXT and enhancing overall signal integrity, an initial analysis of a typical parallel coupled line structure, which is depicted in FIG. 5 at (a), is conducted. The coupled line structure considers two traces on the substrate, designating one as the aggressor line and the other as the victim line. The FEXT is generated from the aggressor line port 1 to victim line port 4, which can be defined as [13]

$$F E X T = \frac{{V}_{in} l}{R T} \times \frac{1}{2 v} \times ( \frac{{C}_{m}}{{C}_{s}} - \frac{{L}_{m}}{{L}_{s}} ) \qquad ( 1 )$$

where Vᵢₙ is the input voltage, l is the physical length of the signal trace, RT is signal rise time, v is signal velocity, Cₘ is mutual capacitance per unit length between two traces, Cₛ is self-capacitance per unit length, L, is mutual inductance per unit length between two traces, Lₛ is self-inductance per unit length. To analyze the intrinsic characteristics of the coupled lines, the far-end coupling coefficient kf is introduced. It serves as a parameter for quantifying the extent of coupling between traces and can be defined as

$${k}_{f} = \frac{1}{2 v} \times ( \frac{{C}_{m}}{{C}_{s}} - \frac{{L}_{m}}{{L}_{s}} ) . \qquad ( 2 )$$

FIG. 5 at (b) depicts capacitive components in a coupled line. The self-capacitance can be expressed as [14]

$${C}_{s} = {C}_{f} + {C}_{p} + {C}_{fe} \qquad ( 3 )$$

where Cₚ is parallel plate capacitance, Cf is external fringing capacitance, and C_{fe} is internal fringing capacitance between the signal and ground conductors. The mutual capacitance can be expressed as

$${C}_{m} = {C}_{ma} + {C}_{m p} + {C}_{m s} \qquad ( 4 )$$

where Cₘₐ, Cₘₚ, and Cₘₛ represent the gap capacitance in the air, the parallel-plate capacitance between the neighbor trace, and the gap capacitance in the substrate, respectively. The self and mutual inductance can be defined as [9]

$$L = [ \begin{matrix}{L}_{s} & {L}_{m} \\ {L}_{m} & {L}_{s}\end{matrix} ] = \frac{1}{{v}_{s}^{2}} \cdot {L}_{2 \times 2} \cdot {C}^{- 1} \qquad ( 5 )$$

where vs symbolizes the wave velocity propagating along the line within the homogeneous media, L_{2×2} is a 2×2 identity matrix, and capacitance matrix C is given as

$$C = [ \begin{matrix}{C}_{s 1} + {C}_{m} & - {C}_{m} \\ - {C}_{m} & {C}_{s 2} + {C}_{m}\end{matrix} ] . \qquad ( 6 )$$

### B. “LL” Shaped Defected Pattern for Self-Inductance Improvement

According to (1) and (2), when k_{f} approaches to zero, the theoretical elimination of FEXT becomes feasible. Therefore, for the practical suppression of FEXT, it is required to either increase the

$$\frac{{C}_{m}}{{C}_{s}}$$

value or decreasing the

$$\frac{{L}_{m}}{{L}_{s}}$$

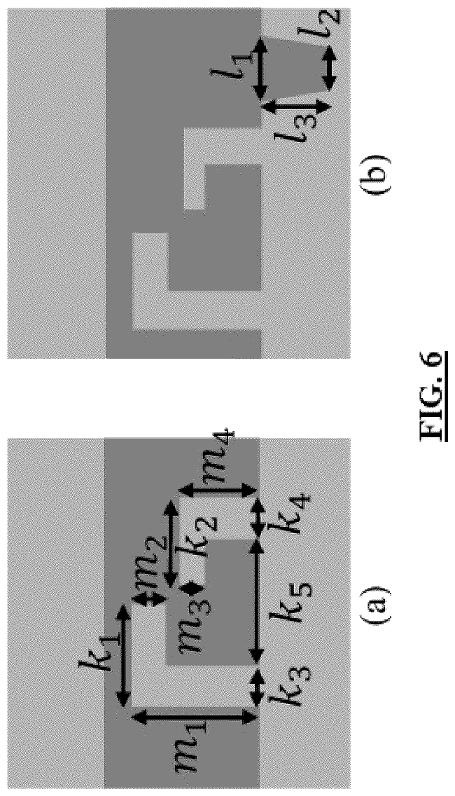

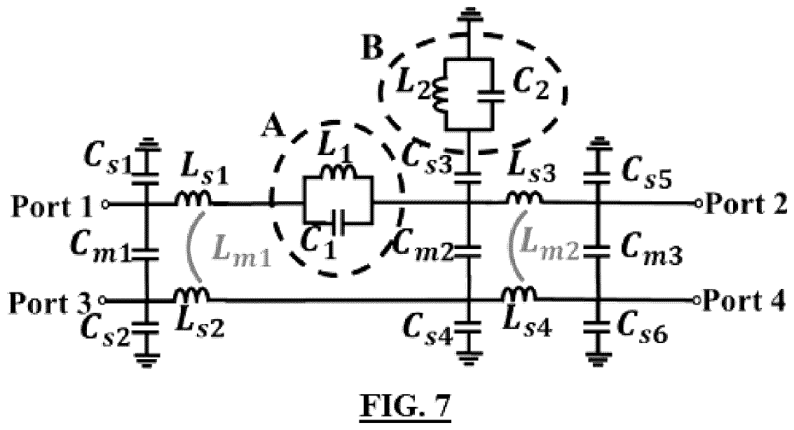

value. To practically mitigate FEXT in the coupled lines, a “LL” shaped defected microstrip structure (DMS) is initially proposed and studied, which is illustrated in FIG. 6 at (a). Similar to the defected ground structure, the DMS structure can be represented with an equivalent shunt LC resonant circuit. FIG. 7 [15] presents the equivalent circuit of the “LL” shaped defected coupled line. Shunt LC circuit A represents the DMS, while shunt LC circuit B represents the coupling effect of the DMS structure with the reference ground, attributing to the opens on the microstrip line which alters the field distribution. In the equivalent circuit, Cₛᵢ (i=1-6) and Lₛᵢ(i=1-4) is self-capacitance and self-inductance of the DMS unit cell, respectively. While Cₘᵢ (i=1-3) and Lₘᵢ (i=1, 2) is mutual capacitance and inductance between the line structures, respectively. Shunt LC resonant circuit A and B composes Cᵢ (i=1, 2) and Lᵢ (i=1, 2), respectively. For the DMS, C₁ and L₁ can be defined as [16]

$${C}_{1} = ( \frac{{ω}_{c}}{{Z}_{0} {g}_{1}} ) \cdot \frac{1}{{ω}_{0}^{2} - {ω}_{c}^{2}} \qquad ( 7 )$$

$${L}_{1} = \frac{1}{{( 2 π {f}_{0} )}^{2} \cdot {C}_{1}} \qquad ( 8 )$$

where ω_{c} donates the cut-off frequency of the shunt LC circuit, ω₀ stands for the resonant frequency of the shunt LC circuit, Z₀ is the characteristic impedance of microstrip line, g₁ represents the normalized parameter of the 1st Butterworth low pass filter, and f₀ is the frequency of the stop band attenuation pole. Through the implementation of “LL” shaped notches, the mutual capacitance from port 1 to port 4 can be expressed as

$${C}_{m} = \frac{{C}_{m 1} \cdot {C}_{1}}{{C}_{m 2} + {C}_{1}} + {C}_{m 2} + {C}_{m 3} \qquad ( 9 )$$

the self-inductance from port 1 to port 2 can be expressed as

$${L}_{s} = {L}_{s 1} + {L}_{1} + {L}_{s 3} . \qquad ( 10 )$$

While for the conventional coupled line structure, mutual capacitance and self-inductance value can be expressed as

$${C}_{m} = {C}_{m 1} + {C}_{m 2} + {C}_{m 3} and \qquad ( 11 )$$

$${L}_{s} = {L}_{s 1} + {L}_{s 3} \qquad ( 12 )$$

respectively.

According to (9)-(12), the proposed “LL” shaped defected coupled line structure enables an improvement in self-inductance and a reduction in mutual capacitance compared to conventional coupled lines, due to the introduction of “LL” patterned notches in lines. To fully analyze the distinctive features of the proposed structure, both coupled line and the proposed structure models are simulated in HFSS and Q3D software to assess the FEXT performance and inductance and capacitance values. A standard Roger RO4350 substrate material (εr=3.66, tan δ=0.004) with a thickness of 0.508 mm is selected to implement the structures. The dimensions of the coupled line are defined with width w=1.08 mm, spacing between traces s=1.2 mm, and copper thickness t=35 μm.

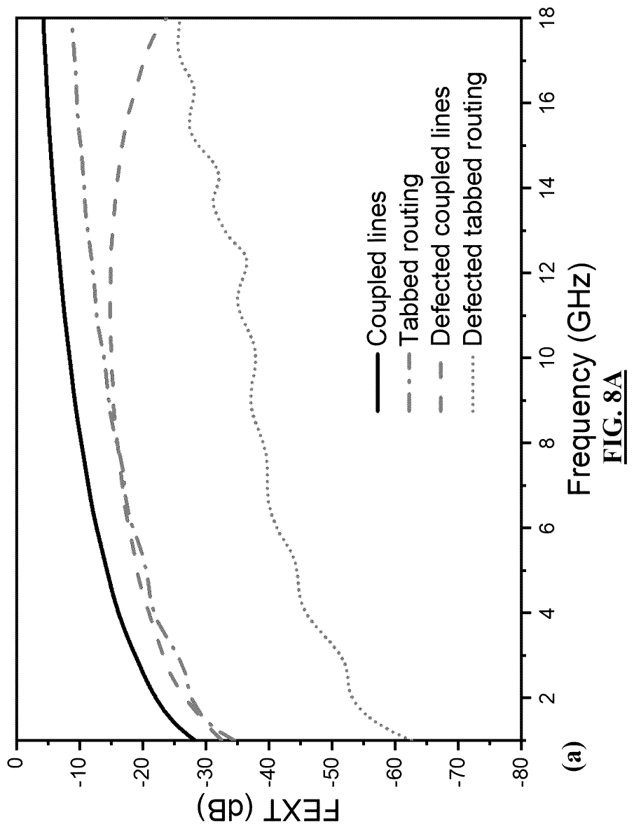

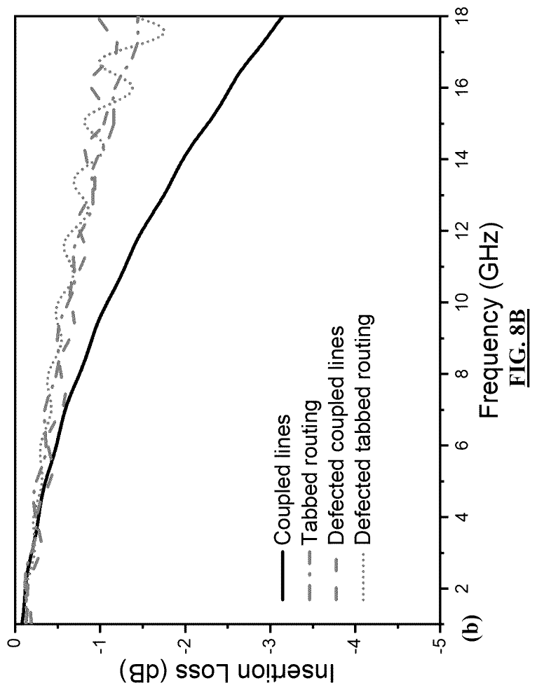

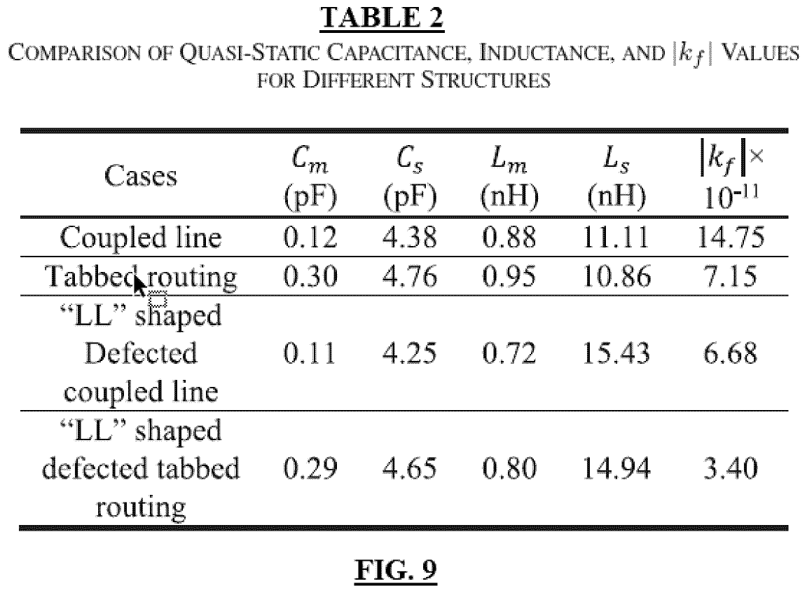

The FEXT performance are graphically presented in FIGS. 8A-8B, while the corresponding inductance and capacitance values are given in Table 2, see FIG. 9. The coupled line structure exhibits mutual capacitance and self-inductance values of 0.12 pF and 11.11 nH, respectively. In comparison, “LL” shaped defected coupled line has the same line width and the same spacing as that of coupled line. The dimensions of the “LL” shaped notch are chosen to be k1=0.75 mm, k2=0.75 mm, k3=0.3 mm, k4-0.3 mm, k5-0.39 mm, m1=0.8 mm, m2=0.1 mm, m3=0.1 mm, and m4=0.5 mm. The distance between defected pattern and tab is 0.1 mm. The periodic unit length is 2.4 mm. The mutual capacitance and self-inductance values of “LL” shaped defected coupled line is 0.11 pF and 15.43 nH, respectively, aligning with (9)-(12). Compared to coupled line structure,

$$\frac{{C}_{m}}{{C}_{s}}$$

value of the proposed LL shaped defect line exhibits minimal increase, whereas the

$$\frac{{L}_{m}}{{L}_{s}}$$

value exhibits significant decrease. According to (2), the far-end coupling coefficient for the coupled line and the “LL” shaped defected coupled line are −14.75×10⁻¹¹ and 6.68×10⁻¹¹ respectively. Notably, the proposed “LL” shaped defected coupled line structure displays a significant improvement in k_{f} compared to the coupled line, which is more approached to zero.

As depicted in FIG. 8A, the FEXT of the proposed structure is effectively reduced from −4.25 dB to −25.85 dB at 18 GHz.

### C. Trapezoidal Shaped Tabs for Mutual Capacitance Improvement

According to the quantity comparison in Table I, the enhancement in the

$$\frac{{C}_{m}}{{C}_{s}}$$

ratio is not conspicuous within the “LL” shaped defected coupled line structure. Consequently, further improvement in FEXT performance can be realized by continuously increasing

$$\frac{{C}_{m}}{{C}_{s}}$$

value. To realize this, short trapezoidal shaped tabs are introduced along the microstrip line. The unit of “LL” shaped defected tabbed routing structure is illustrated in FIG. 6 at (b) with tab dimensions defined as l1=0.52 mm, l2=0.4 mm, and l3=0.7 mm. The line width and the spacing are kept the same.

The additional fringe capacitance between the tab end and the trace is induced, contributing to the enhancement of the Cₘₚ, which further increases the Cm value. This additional fringe capacitance can be expressed as [12]

$${C}_{fa} = \frac{1}{2} \cdot ( \frac{1}{{c}_{0} {Z}_{t}} - {ε}_{0} \frac{{l}_{1} + {l}_{2}}{2 {s}_{1}} ) \qquad ( 13 )$$

where Zₜ is the characteristic impedance of the single-ended microstrip line with air as substrate [17] and s₁ is the distance between the tab to the trace. According to (4) and (13), the mutual capacitance from port 1 to port 4 can be rewritten as

$${C}_{m} = \frac{{C}_{m 1} \cdot {C}_{1}}{{C}_{m 1} + {C}_{1}} + {C}_{m 2} + {C}_{m 3} + {C}_{fa} \qquad ( 14 )$$

which reveals that the mutual capacitance can be improved by implementing the tabs along the traces. To comprehensively analyze the performance of the proposed “LL” shaped defected tabbed routing structure, the model is simulated in HFSS and Q3D to evaluate FEXT, capacitance, and inductance values. The results are illustrated in FIGS. 8A and 8B and Table, 2, see FIG. 9, respectively.

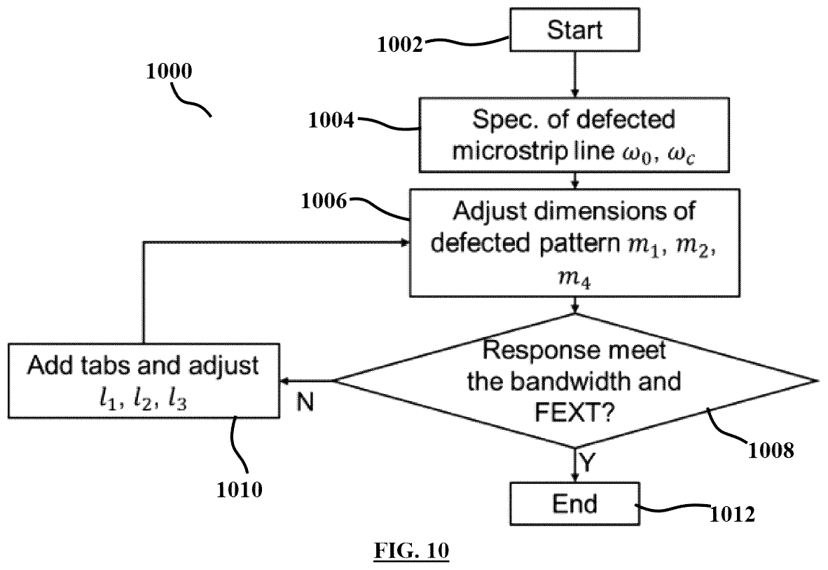

The mutual capacitance for the tabbed routing structure and the “LL” shaped defected tabbed routing structure are 0.30 and 0.29 pF, respectively, which aligns with the formulaic model as expected. Compared to the coupled line structure, the proposed structure exhibits increment in both mutual capacitance and self-inductance, leading to concurrent improvement of capacitive coupling and reduction of inductive coupling. Considering capacitances, inductances, and the absolute values of k_{f} as given in Table 2, see FIG. 9, the coupled line structure has the highest |kf|value. Both the tabbed routing structure and the proposed “LL” shaped defected coupled line structure demonstrate a reduction in |kf| to a certain degree by merely increasing mutual capacitance or self-inductance. Notably, the proposed “LL” shaped defected tabbed routing structure further reduces the |kf| value, which is only 3.4×10-11, resulting in a remarkable low FEXT. As shown in FIG. 8A, the proposed “LL” shaped defected tabbed routing structure has the best FEXT performance as expected. The insertion loss ripples FIG. 8B are mainly due to the deformation of the geometry leading to the impedance mismatch and discontinuity, which can be optimized by impedance matching. The design procedure flow of the “LL” shaped defected tabbed routing structures is shown in FIG. 10.

FIG. 10 shows process 1000 with start 1002. At step 1004, the specification of defected microstrip line w₀, we are determined. At step 1006, the dimensions of the defected pattern m1, m2, and 4 are adjusted. At step 1008, in inquiry posits if the desired band with and FEXT are met. If not, at step 1010, tabs may be added as l₁, l₂, and l₃ adjusted as well as returning to step 1006 for further adjustments, then returning to the step 1008 to repeat the inquiry. If the desired bandwidth and FEXT are achieved, the process may reach end step 1012. If not, the process may undergo steps 1010, 1006, and 1008 until the desired results are achieved.

### III. Measurement Results and Discussions

### A. Fabrication and S-Parameters Analysis

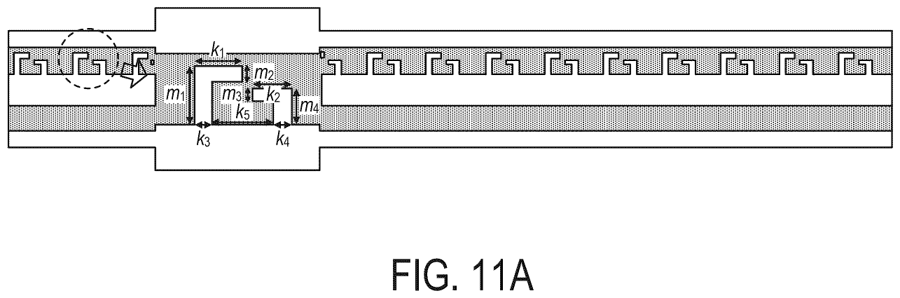

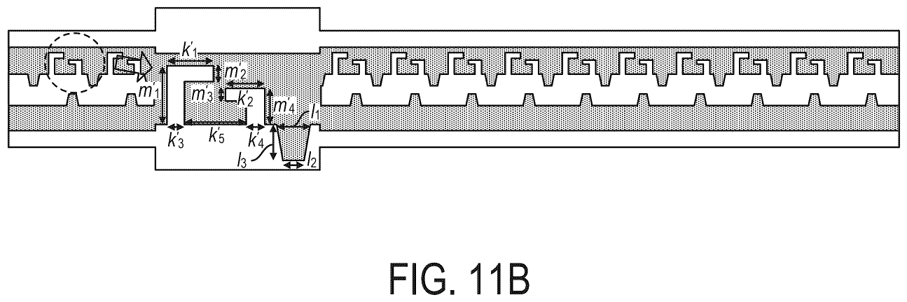

For case of fabrication and cost efficiency, the proposed structure, coupled line, and tabbed routing structure are constructed on an FR-4 PCB with εr=4.6, tan δ=0.015, and a thickness of 0.6 mm. Same dimensions are assigned to all structures: trace width is set as w=1.1 mm, the space between traces is s=1.1 mm, copper thickness is t=18 μm, and the trace length is b=40 mm. The schematic representations of the proposed “LL” shaped defected coupled line and the “LL” shaped defected tabbed routing structure are illustrated in FIGS. 11A and 11B, respectively.

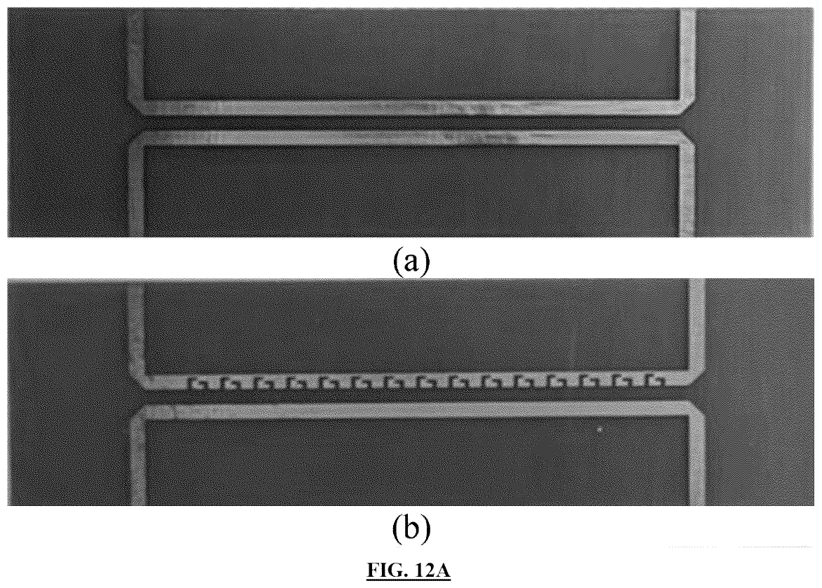

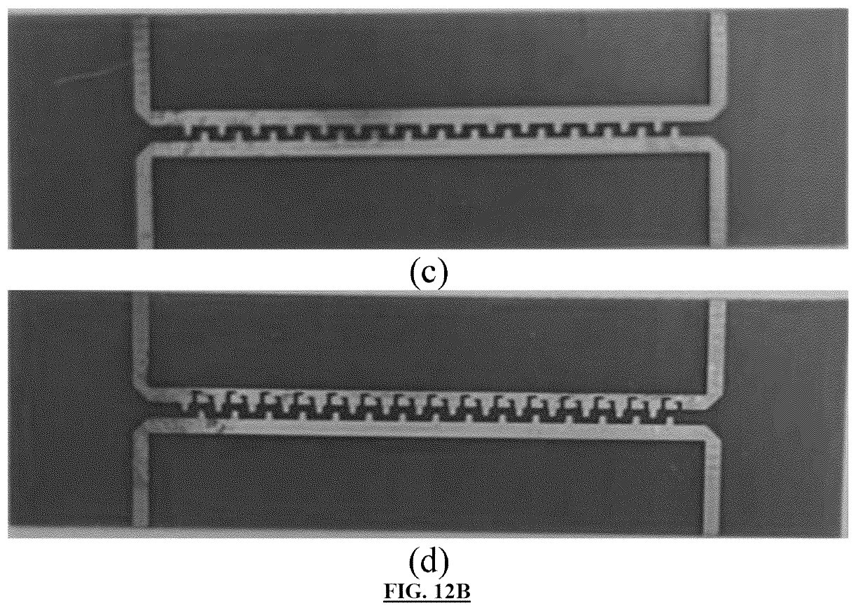

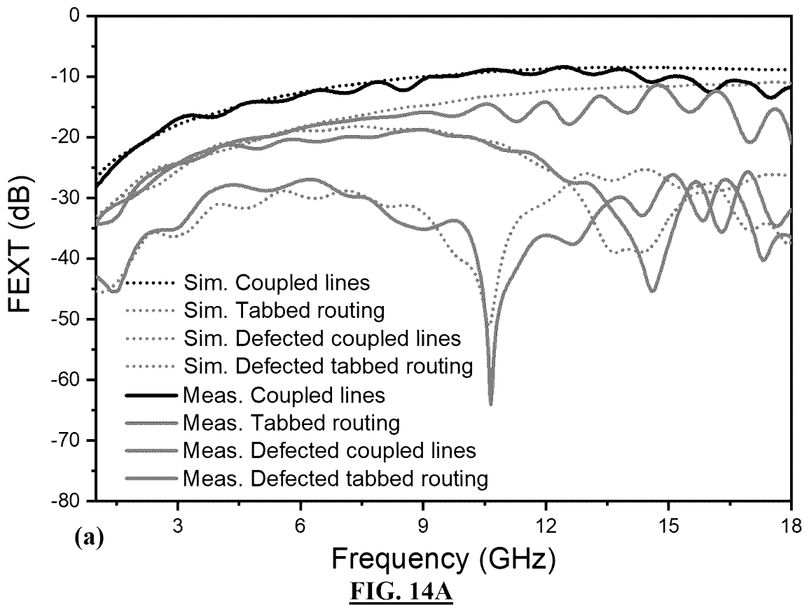

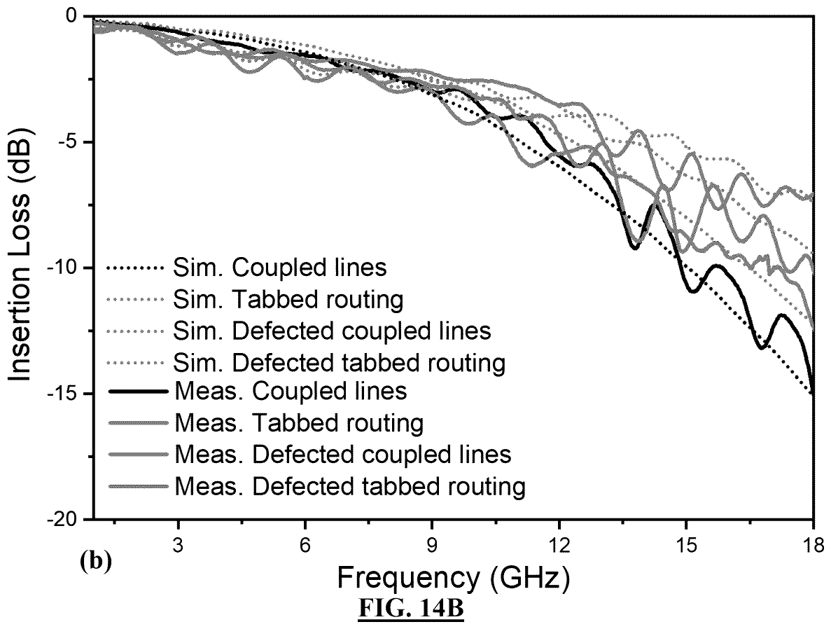

The dimensions for the “LL” shaped defected coupled line are chosen to be k₁=0.7 mm, k₂=0.7 mm, k₃=0.3 mm, k₄+=0.3 mm, k₅=0.9 mm, m₁=0.9 mm, m₂=0.2 mm, m₃=0.2 mm, and m₄=0.6 mm, while “LL” shaped defected tabbed routing structure is defined with dimensions k′₁=0.7 mm, k′₂=0.7 mm, k′₃=0.3 mm, k′₄=0.3 mm, k′₅=0.9 mm, m′₁=0.9 mm, m′₂=0.2 mm, m′₃=0.2 mm, m′₄=0.6 mm, l₁=0.52 mm, l₂=0.4 mm, and l₃=0.5 mm. The distance between defected pattern and tab is 0.1 mm. The periodic unit length is 2.4 mm. Fabrication device diagrams for each structure are depicted in FIGS. 12A and 12B at (a), (b), (c), and (d). The S-parameters measurement is conducted with a R&S ZVA 67 vector network analyzer (VNA). Measured and simulated S-parameters are shown in FIGS. 14A and 14B. A small deviation was found between the simulation and measurement results, primarily stemming from the slightly different dimensions of the fabricated structures from the design and the mismatch from the connectors. Nevertheless, the trends observed in measurement results are essentially consistent with the simulation results, which fully demonstrate the efficacy of the proposed structure concept.

The results show that both “LL” shaped defected coupled line and “LL” shaped tabbed routing structure have greatly reduced FEXT. Specifically, for “LL” shaped defected coupled line, a maximum reduction of 33 dB in FEXT is observed at 14.6 GHz. Remarkably, FEXT of “LL” shaped tabbed routing structure experiences a significant reduction of 55 dB at 10.6 GHz. The maximum FEXT reduction occurs at the frequency due to the resonance controlled by the “LL” defected patterns periodical distance and the total length of input/output line. It also achieves a noteworthy reduction in FEXT by at least 15 dB within the wide operation frequency range of 1-18 GHZ.

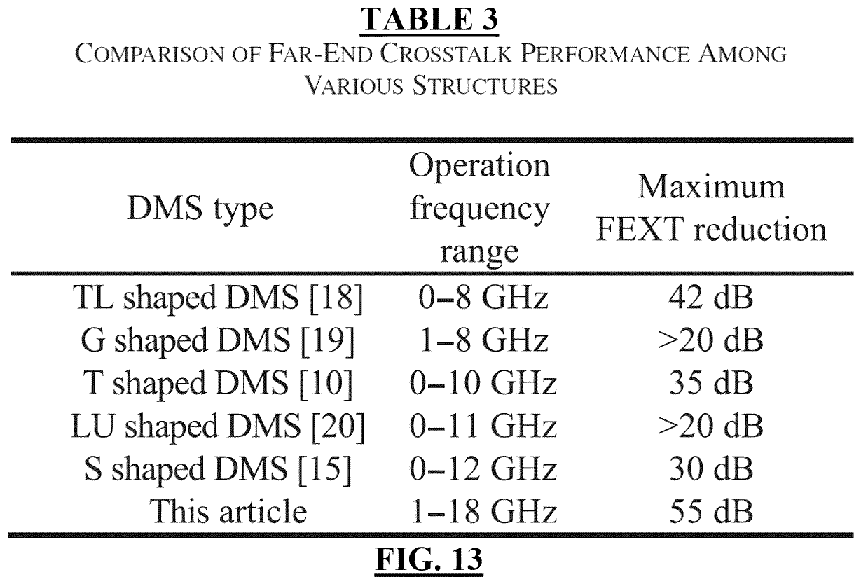

“LL” shaped defected tabbed routing structure also showcases superior insertion loss performance compared to other three structures, which is due to less energy being transferred to the adjacent line with the reduced FEXT. Consequently, less energy is dissipated and absorbed by the adjacent line, preserving the signal integrity in the primary transmission path. It is noteworthy that the proposed structure exhibits operational capabilities up to Ku band, while previous studies have only achieved success up to X band. A comparative analysis of the proposed structure with previous work is given in Table 3, see FIG. 13. Notably, this disclosure boasts the widest bandwidth compared to previous research, representing a substantial improvement in operation frequency range, particularly due to the prior work were limited by the low cut-off frequency induced by the notches in the microstrip line. Additionally, the proposed structure has excellent FEXT performance, outperforming previous studies.

### B. Eye Diagrams Analysis

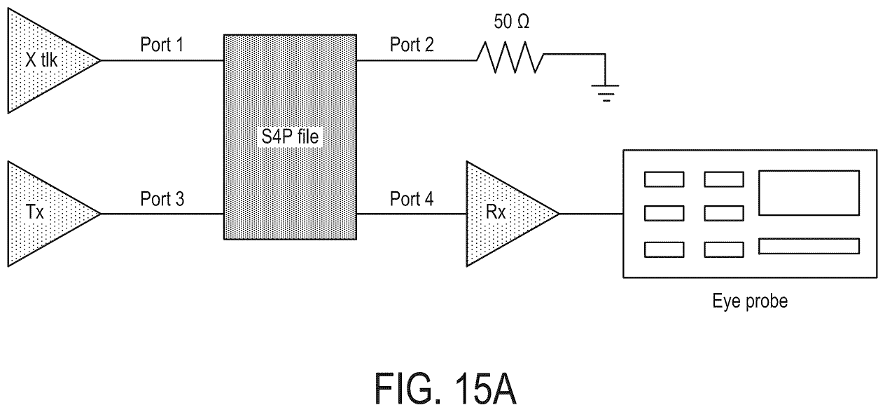

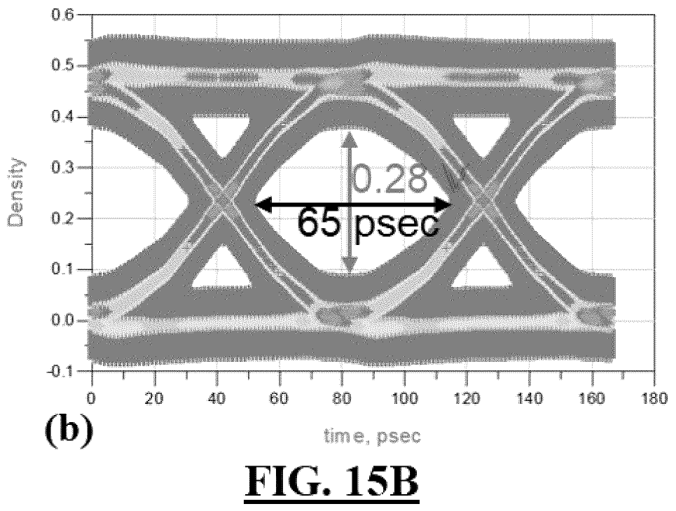

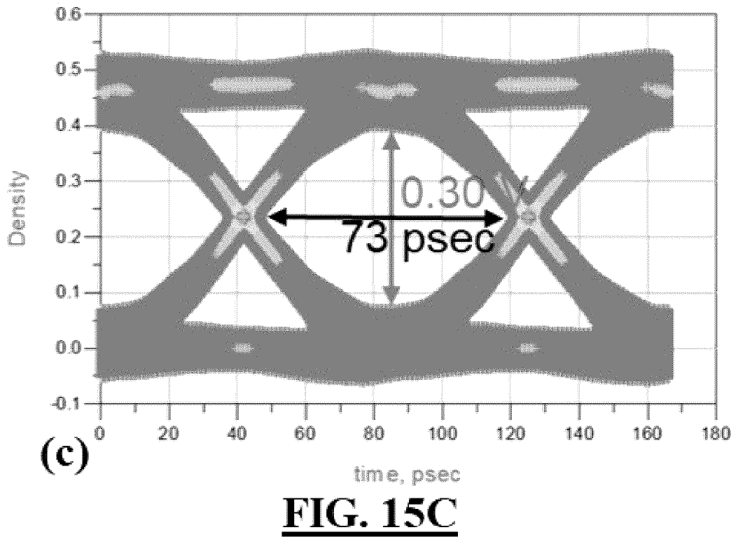

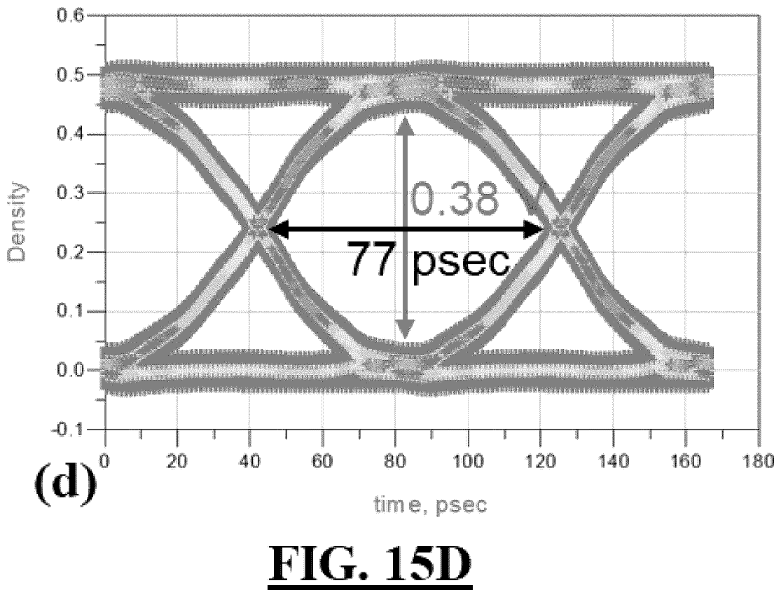

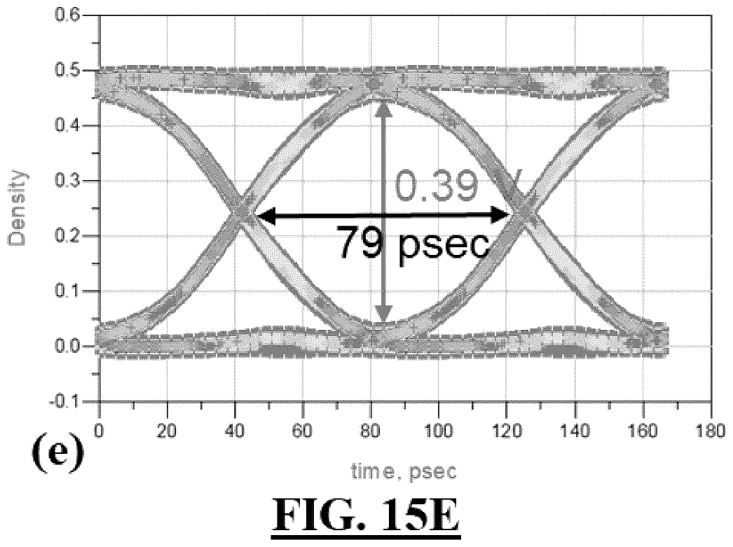

To assess the high-speed data transfer performance of the proposed structure, the measured touchstone files exported from VNA are imported into advanced design system (ADS) software to simulate corresponding eye diagrams. The circuit schematic is depicted in FIG. 15A. For comparative analysis, a high-speed signal of 12-Gb/s, generated by pseudorandom binary sequence with a rise/fall time of 50-ps and strength of 1V is applied to the transmitter (Tx) port, port 3. All ports impedance are 50 ohms. The Xtlk from port 1 is adjusted to match the signal swing at Tx but with a randomized relative phase. To generate eye diagrams, the eye probe is placed at the receiver (Rx) port, port 4, which can detect the impact of asynchronous Xtlk on the channel performance. FIGS. 15A-15E at (b), (c), (d), and (e), respectively, illustrate the eye diagrams for all structures, revealing a trend consistent with the measurement S-parameter results. In the case of conventional coupled line structure, the eye height and width are merely 0.28 V and 65 psec, respectively, and the jitter is 19 psec. Within the tabbed routing structure, the eye-opening improves to 0.30 V and 73 psec with a reduced jitter of 10 psec, while within the “LL” shaped defected coupled line structure, eye opening height is 0.38 V with a width of 77 psec and a reduced jitter of 6 psec, attributing to the reduction in FEXT to a certain degree. Notably, the “LL” shaped defected tabbed routing structure achieves the greatest eye opening and the smallest jitter among these four structures, with an eye height of 0.39 V, a width of 79 psec, and a jitter of 4 psec.

### IV. Conclusion

This disclosure presents an innovative approach to mitigate FEXT in coupled line by incorporating “LL” shaped defected patterns and a tabbed routing structure. The methodology is thoroughly analyzed through equivalent circuit model and is fully validated with electromagnetic simulations and practical measurements of implemented prototypes. The measurement results demonstrate the efficacy and feasibility of the proposed structures in reducing FEXT. In comparison to conventional coupled line, this novel structure achieves a noteworthy reduction in FEXT by at least 15 dB within the operation frequency from 1 to 18 GHZ, and a maximum FEXT reduction of 55 dB at 10.6 GHz. Furthermore, when compared to coupled line featuring merely short trapezoidal shaped tabs, the proposed structure still exhibits superior FEXT performance. Comparative analysis with prior DMS-based methods also underscores the improved FEXT performance and extended operation frequency range of the proposed structure. Additionally, this disclosure contributes to a deep understanding of defected tabbed routing structure through equivalent circuit analysis and calculation of corresponding far-end coupling coefficient k_{f} value. With improved FEXT performance, wide bandwidth, and case of fabrication, the proposed work enables a promising solution to address crosstalk challenges in high-speed integrated circuits and systems, which contribute to improved signal integrity and overall performance in electronic systems.

### REFERENCES

All references are hereby incorporated by reference to the extent not inconsistent herewith.
[1] J. Lim, S. Lee, Y. Jeong, and J. Lee, “A novel method using a rectangular groove to reduce far-end crosstalk in microstrip lines covered with a dielectric layer,” IEEE Access, vol. 7, pp. 93643-93652, 2019.
[2] M. I. Montrose, Printed Circuit Board Design Techniques for EMC Compliance. Piscataway, NJ, USA: IEEE Press, 1996.
[3] Z. Li, Q. Wang, and C. Shi, “Application of guard traces with vias in the RF PCB layout,” in Proc. 3rd Int. Symp. Electromagn. Compat., May 2002, pp. 771-774.
[4] W.-T. Huang, C.-H. Lu, and D.-B. Lin, “Suppression of crosstalk using serpentine guard trace vias,” Prog. Electromagn. Res., vol. 109, pp. 37-61, 2010.
[5] X. Dai, W. Feng, and W. Che, “Reduction of UWB far-end crosstalk in microwave and millimeter-wave band of parallel periodically loaded transmission lines with discontinuous structured guard lines,” IEEE Trans. Plasma Sci., vol. 48, no. 7, pp. 2372-2383 July 2020.
[6] B.-R. Huang, K.-C. Chen, and C.-L. Wang, “Far-end crosstalk noise reduction using decoupling capacitor,” IEEE Trans. Electromagn. Compat., vol. 58, no. 3, pp. 836-848, June 2016.
[7] X.-B. Yu, Q.-M. Cai, Y. Ren, X. Ye, and J. Fan, “Study of thickening soldermask coated microstrip lines on high-speed PCBs for crosstalk reduction in DDR5,” in Proc. IEEE Int. Symp. Electromagn. Compat. Signal/Power Integrity, July/August 2020, pp. 575-577.
[8] S. K. Lee, K. Lee, H. J. Park, and J. Y. Sim, “FEXT-eliminated stubalternated microstrip line for multi-gigabit/second parallel links,” Electron. Lett., vol. 44, no. 4, pp. 272-273, 2008.
[9] W. Jiang, X.-D. Cai, B. Sen, and G. Wang, “Equation-based solutions to coupled, asymmetrical, lossy, and nonuniform microstrip lines for tabrouting applications,” IEEE Trans. Electromagn. Compat., vol. 61, no. 2, pp. 548-557, April 2019.
[10] M. Kazerooni, M. A. Salari, and A. Cheldavi, “A novel method for crosstalk reduction in coupled pair microstrip lines,” Int. J. RF Microw. Comput.-Aided Eng., vol. 22, no. 2, pp. 167-174, 2012.
[11] L. K. Baghel, S. Kumar, S. A. Sis, and J. Kim, “Crosstalk reduction in coupled microstrip lines using TT-shaped DMS approach,” in Proc. Joint Asia-Pac. Int. Symp. Electromagn. Compat. Int. Conf. Electromagn. Interference Compat., May 2023, pp. 1-4.
[12] J. Ge, R. Floyd, A. Khan, and G. Wang, “High-performance interconnects with reduced far-end crosstalk for high-speed ICs and communication systems,” IEEE Trans. Compon., Packag. Manuf. Technol., vol. 13, no. 7, pp. 1013-120 July 2023.
[13] E. Bogatin, Signal and Power Integrity-Simplified. London, U.K.: Pearson, 2010, ch. 10.
[14] S. M. Perlow, “Analysis of edge-coupled shielded strip and slabline structures,” IEEE Trans. Microw. Theory Technol., vol. 35, no. 5, pp. 522-529, May 1987.
[15] X. Liu et al., “Equivalent circuit model of crosstalk reduction parallel transmission lines with defected microstrip structures,” in Proc. Cross Strait Quad-Regional Radio Sci. Wireless Technol. Conf., July 2018, pp. 1-2.
[16] T. Jiang, Y. Wang, and Y. Li, “Design and analysis of a triple stop-band filter using ratioed periodical defected microstrip structure,” Frequenz, vol. 71, no. 7-8, pp. 341-347, 2017.
[17] S. S. Bedair, “Characteristics of some asymmetrical coupled transmission lines (short paper),” IEEE Trans. Microw. Theory Technol., vol. 32, no. 1, pp. 108-110, January 1984.
[18] C. Li, Y. Wang, and X. Li, “Crosstalk reduction between microstrip lines using TL-shaped defected microstrip structure,” Eng. Rep., vol. 5, no. 1, 2023, Art. no. e12559.
[19] R. Li, Y. Wang, W. Yang, and X. Li, “G-shaped defected microstrip structure-based method of reducing crosstalk of coupled microstrip lines,” Prog. Electromagn. Res. M, vol. 5, no. 1, 2021, Art. no. e12599.
[20] Y. V., G. N. Alsath, and M. Kanagasabai, “Defected microstrip structure based near-end and far-end crosstalk mitigation in high-speed PCBs for mixed signals,” Microelectronics Int., vol. 41, no. 1, pp. 16-25, 2024.

Various modifications and variations of the described methods, pharmaceutical compositions, and kits of the disclosure will be apparent to those skilled in the art without departing from the scope and spirit of the disclosure. Although the disclosure has been described in connection with specific embodiments, it will be understood that it is capable of further modifications and that the disclosure as claimed should not be unduly limited to such specific embodiments. Indeed, various modifications of the described modes for carrying out the disclosure that are obvious to those skilled in the art are intended to be within the scope of the disclosure. This application is intended to cover any variations, uses, or adaptations of the disclosure following, in general, the principles of the disclosure and including such departures from the present disclosure come within known customary practice within the art to which the disclosure pertains and may be applied to the essential features herein before set forth.

What is claimed is:

1. An interconnect structure for reducing far-end crosstalk comprising:
at least two traces formed substantially parallel to one another;
a pattern etched onto at least one of the traces; and
the interconnect structure having a frequency from 1 to 18 GHz and a maximum FEXT reduction of up to 55 dB at 10.6 GHz.

2. The interconnect structure of claim 1, further comprising wherein the pattern etched into the at least one trace comprises an LL shape etched at multiple locations on the at least one trace.

3. The interconnect structure of claim 2, further comprising wherein the pattern etched into the at least one trace comprises notches defined within a material forming the at least one trace.

4. The interconnect structure of claim 1, further comprising wherein the pattern etched on the at least one trace improves a self-inductance of the at least one trace as compared to a different trace with no pattern etched on the different trace.

5. The interconnect structure of claim 1, further comprising a series of tabs formed onto at least one of the at least two traces.

6. The interconnect structure of claim 5, further comprising wherein the series of tabs improves a mutual capacitance value of the at least one trace as compared to a second different trace with no series of pattern etched on the second different trace.

7. The interconnect structure of claim 5, further comprising wherein the series of tabs are shaped as trapezoidal tabs.

8. The interconnect structure of claim 5, further comprising wherein self-inductance and mutual capacitance of the at least one of the two traces is adjustable by configuring both the pattern etched and the series of tabs on the at least one of the traces.

9. The interconnect structure of claim 1, further comprising wherein FEXT is reduced via concurrently increasing a mutual capacitance between adjacent traces and self-inductance of the at least two traces.

10. The interconnect structure of claim 1, further comprising decreasing FEXT by at least 15 dB within an operation frequency range of 1 to 18 GHz.

11. A method for reducing far-end crosstalk comprising:
configuring an interconnect structure to comprise:
at least two traces formed substantially parallel to one another;
a pattern etched onto at least one of the traces; and
configuring the interconnect structure to have a frequency from 1 to 18 GHz and a maximum FEXT reduction of up to 55 dB at 10.6 GHz.

12. The method for reducing far-end crosstalk of claim 11, further comprising configuring the pattern etched into the at least one trace to form an LL shape etched at multiple locations on the at least one trace.

13. The method for reducing far-end crosstalk of claim 12, further comprising configuring the pattern etched into the at least one trace to comprise notches defined within a material forming the at least one trace.

14. The method for reducing far-end crosstalk of claim 11, further comprising configuring the pattern etched on the at least one trace to improve a self-inductance of the at least one trace as compared to a different trace with no pattern etched on the different trace.

15. The method for reducing far-end crosstalk of claim 11, further comprising configuring a series of tabs formed onto at least one of the at least two traces.

16. The method for reducing far-end crosstalk of claim 15, further comprising configuring the series of tab to improve a mutual capacitance value of the at least one trace as compared to a second different trace with no series of pattern etched on the second different trace.

17. The method for reducing far-end crosstalk of claim 15, further comprising configuring the series of tabs as trapezoidal tabs.

18. The method for reducing far-end crosstalk of claim 15, further comprising adjusting self-inductance and mutual capacitance of the at least one of the two traces via configuring both the pattern etched and the series of tabs on the at least one of the traces.

19. The method for reducing far-end crosstalk of claim 11, further comprising reducing FEXT via concurrently increasing a mutual capacitance between adjacent traces and self-inductance of the at least two traces.

20. The method for reducing far-end crosstalk of claim 11, further comprising configuring the interconnect structure to decrease FEXT by at least 15 dB within an operation frequency range of 1 to 18 GHz.
